(19) United States
(12) Patent Application Publication
(10) Pub. No.: US 2012/0025262 A1
(43) Pub. Date: Feb. 2, 2012

(54) MOS Type Semiconductor Device and Method of Manufacturing Same

(75) Inventor: Yasushi NIIMURA, Matsumoto-city (JP)

(73) Assignee: FUJI ELECTRIC CO., LTD., Kawasaki-shi (JP)

(21) Appl. No.: 13/195,516

(22) Filed: Aug. 1, 2011

(30) Foreign Application Priority Data
Aug. 2, 2010 (JP) 2010-173563

(51) Int. Cl. H01L 29/78; H01L 21/266; H01L 29/739

(52) U.S. Cl. 257/139; 257/329; 438/527; 257/E29.197; 257/E29.257; 257/E21.346

(57) ABSTRACT

An object of the present invention is to provide a MOS type semiconductor device allowing production at a low cost without lowering a breakdown voltage and avoiding increase of an ON resistance. A MOS type semiconductor device of the invention comprises: a p base region having a bottom part in a configuration with a finite radius of curvature and selectively disposed on a front surface region of a n⁻ drift layer; an n type first region selectively disposed on a front surface region of the p base region; a gate electrode disposed on a part of the surface of the p base region between a surface of the n type first region and a front surface of the n⁻ drift layer interposing a gate insulation film between the part of the surface of the p base region and the gate electrode; and a metal electrode in electrically conductive contact with the front surface of the n type first region and the central part of the surface of the p base region; wherein a pn junction surface between the base region and the drift layer has centers of curvature both at the outside and inside of the base region.

### CROSS-REFERENCE TO RELATED APPLICATION

This application is based on, and claims priority to, Japanese Patent Applications No. 2010-173563, filed on Aug. 2, 2010, contents of which are incorporated herein by reference.

### BACKGROUND OF THE INVENTION

1. Field of the Invention

The present invention relates to a MOS (metal oxide semiconductor) type semiconductor device such as a MOSFET (a MOS field effect transistor) and an IGBT (an insulated gate bipolar transistor), and a method of manufacturing the MOS type semiconductor device.

2. Description of the Related Art

Power MOSFETs and IGBTs, which are MOS type semiconductor devices, are known as voltage-controllable devices. FIG. 9 is a sectional view of an essential part of a conventional MOSFET. A p base region 17 is formed on a front surface layer of an n⁻ drift layer 1 adjacent to an n⁺ drain layer 2 that is a substrate. On the front surface region of the p base region 17, an n⁺ source region 6 and a p⁺ contact region 22 are selectively formed. A channel-forming region 7 appears in the front surface layer of the p base region 17 that is located between the surface of the n⁻ drift layer 1 and the surface of the n⁺ source region 6. A gate electrode 8 is provided on the channel forming region 7 through a gate insulation film 9. An interlayer dielectric film 10 is formed on the gate electrode 8 and holds electric insulation from a source electrode 13 that covers the interlayer dielectric film 10. The source electrode 13 is formed so as to be in contact commonly with a surface of the p⁺ contact region 22 and a surface of the n⁺ source region 6. A drain electrode 12 is formed on a surface of an n⁺ drain layer 2 on the rear surface side.

A junction surface 20 at which the p base region 17 and the n⁻ drift layer 1 is in contact with each other consists of a peripheral section with a finite radius of curvature and a bottom section with ordinarily flat configuration. The bottom section can be not flat but so curved that the depth from the surface of the p base region 17 to the junction surface 20 is the deepest at the center of the p base region 17 as shown in FIG. 13, which is disclosed in Patent Document 1. The configuration of the bottom surface becomes flat when the width of the ion injection region is larger than the range of the injected impurity ions in the process of forming the p base region 17 and becomes not flat when the width is smaller than the range. In addition, a p⁺ contact region 22 reaching the place right under the source region 6 is provided in many cases as shown in FIG. 9 and FIG. 13 in order to achieve good contact characteristic with the source electrode 13 and reduce influence of a parasitic bipolar transistor, which will be described afterwards.

A wafer process for the conventional MOSFET shown in FIG. 9 is described in the following. The MOSFET uses a semiconductor substrate comprising a high concentration n type silicon substrate to become an n⁺ drain layer 2, and an n⁻ drift layer 1 with high resistivity epitaxially grown on the n type silicon substrate. After forming a gate insulation film 9 on the n⁻ drift layer 1, a polycrystalline silicon layer is deposited for forming a gate electrode 8. This polycrystalline silicone layer is patterned by photolithography technique to form a gate electrode 8 of polycrystalline silicon. Boron ion injection is executed, followed by a thermal diffusion process, through the opening in the polycrystalline silicon layer utilizing the electrode 8 as a mask to form a p base layer 17. Then, donor ions such as arsenic are injected to form an n⁺ source region 6 using a mask composed of the gate electrode 8 and a photoresist (not shown in the figure) or a mask composed of the gate electrode 8 and a part of the oxide film selectively left at the central region of the opening. After removing the oxide film mask in the central region of the opening, a p⁺ contact region 22 is formed. Except for the surface of the n⁺ source region 6 and the surface of the p⁺ contact region 22, the whole front surface including the surface of the gate electrode 8 is covered with an interlayer dielectric film 10. Then, an opening is formed, by the lithography technique, in the region for making the n⁺ source region 6 and the p⁺ contact region 22 to become in contact with a source electrode 13 in the next step. The source electrode 13 is deposited to be commonly in contact with the n⁺ source region 6 and the p⁺ contact region 22 and insulated from the gate electrode 8 with the interposed interlayer dielectric film 10. On the surface of an n⁺ drain layer 2 in the rear surface side, a drain electrode 12 of a plurality of well known metal films is laminated. Thus, the main steps of the wafer process for the MOSFET are completed. The step for forming the n⁺ source region 6 and the step for forming the p⁺ contact region 22 are exchanged in some cases.

In operation of the MOSFET, a channel is formed in the channel-forming region 7 right under the gate insulation film 9 when a positive voltage, with respect to the potential of the source electrode 13, is applied onto the gate electrode 8. As a result, electrons are injected from the n⁺ source region 6 through the channel-forming region 7 into then drift region 1 giving rise to a conducting state. When the gate electrode 8 is biased at an equal or negative potential with respect to the source electrode 13, a blocked state results. Thus, the MOSFET operates as a so-called switching device.

FIG. 10 is a sectional view of an essential part of a conventional IGBT. The IGBT of FIG. 10 is different from the MOSFET of FIG. 9 in that the n⁺ drain layer 2 is replaced by a p⁺ collector layer 14 and an n⁺ buffer layer 15 is additionally formed between the p⁺ collector layer 14 and the n⁻ drift layer 1. The n⁻ drift layer 1 and the n⁺ buffer layer 15 formed on the collector layer 14 by epitaxial growth become a semiconductor substrate for forming a MOS structure on the front surface side of the substrate. On the front surface region of the n⁻ drift layer 1 of the semiconductor substrate, the regions of the MOS structure are formed through the same steps as those in the process described above for the MOSFET. Operation of the IGBT is different from that of the MOSFET in that positive holes are injected from the p⁺ collector layer 14 and conductivity modulation arises in the n⁻ drift layer resulting in a low resistivity state of the n⁻ drift layer.

In the manufacturing process of the MOSFET and the IGBT, the n⁺ source region 6 and the p base region 17 are generally formed by a so-called self alignment technology using the gate electrode 8 as a mask. The n⁺ source region 6 and the p base region 17 can also be formed by other methods as disclosed in Patent Documents 1 and 3. In one of the methods, the p base region 17 is formed using a resist mask and the n⁺ source region 6 is formed using a polycrystalline silicon mask. In another of the methods, the p base region 17 and the n⁺ source region 6 are formed using photoresist masks dedicated for the respective regions.

Patent Document 2 discloses a similar MOSFET having a structure for avoiding breakdown of a device due to turning ON of a parasitic bipolar transistor during a turn OFF process in an inductive load circuit. This structure comprises an n well region formed in the central part of a p type channel diffusion layer, which corresponds to the p base region 17. This structure, according to the description in Patent Document 2, prevents the parasitic bipolar transistor from turning ON. Patent Documents 4 and 5 disclose a structure comprising a p type region, which corresponds to the p base region 17, having a bottom part including two downwardly protruding portions.

[Patent Document 1] Japanese Unexamined Patent Application Publication No. H09-148566
[Patent Document 2] Japanese Unexamined Patent Application Publication No. H07-235668

### [Patent Document 3] Japanese Unexamined Patent Application Publication No. 2009-277839

[Patent Document 4] Japanese Unexamined Patent Application Publication No. H06-163909
[Patent Document 5] Japanese Unexamined Patent Application Publication No. H08-204175

When the conventional MOSFET and IGBT are used in an inverter in connection to an inductive load, however, breakdown of the device frequently occurs on turning OFF of the device. The breakdown is caused by the following mechanism. FIG. 11 is a sectional view of an essential part of a conventional MOSFET overlapped by an equivalent circuit of the MOSFET. The MOSFET contains a parasitic bipolar transistor 30 composed of the n⁺ source region 6, the p base region 17, and the n⁻ drift layer 1. When the MOSFET turns OFF in a circuit with an inductive load, the channel-forming region 7 changes into a blocked condition, stopping the electron injection from the n⁺ source region 6 into the n⁻ drift layer 1, and a depletion layer expands in the n⁻ drift layer 1. In this time, the drain-source voltage applied to the MOSFET may rise above a breakdown voltage of the MOSFET and an avalanche current runs in the MOSFET to consume the energy that have been stored in the inductive load. In this process, the curved parts of the p base region 17 become avalanche arising parts 16, as shown in FIG. 12, generating hole-electron pairs. The holes generated in the curved part constitute an avalanche current 34 as indicated by the arrow in FIG. 12 and flow laterally in the p base region 17 right under the n⁺ source region 6. If the avalanche current grows high, the voltage drop due to the lateral resistance R in the p base region 17 may exceed the built-in potential (0.7 to 0.8 volts) at the pn junction between the p base region 17 and the n⁺ source region 6. Then, electron injection from the n⁺ source region 6 arises to turn the parasitic bipolar transistor 30 ON, resulting in local current concentration and device breakdown. In order to cope with this problem, a means have been devised in which the voltage drop in the lateral resistance R is reduced below the built-in potential by disposing a p⁺ contact region 22 at the lateral current path right under the n⁺ source region 6. However, if the p⁺ contact region 22 is extended into the channel-forming region 7, a channel is not formed despite application of a positive voltage on the gate electrode 8 and thus, a switching function cannot be performed. It is therefore necessary to design the p⁺ contact region 22 to be separated from the channel-forming region 7 with a certain distance in consideration of an error in processing. Consequently, the lateral resistance R remains at a certain magnitude and possibility of turning ON of the parasitic bipolar transistor 30 is not fully eliminated, causing breakdown of the device.

Another method is known for preventing the parasitic bipolar transistor from turning ON as shown by the sectional view of an essential part of a MOSFET in FIG. 14 and an IGBT in FIG. 15, in which a second p⁺ region 21 deeper than the p base region 17 is formed to concentrate the avalanche current at the bottom part of the second p⁺ region 21. However, there is another problem in this structure that the breakdown voltage decreases due to an irregular configuration of the pn junction surface composed of the p base region 17 and the second p⁺ region 21. Still another problem causing decrease in the breakdown voltage arises due to decreased thickness of the n⁻ drift layer 1 between the bottom part of the deeply diffused second p⁺ region 21 and the n⁺ drain layer 2. On the other hand, this construction does not change the current path of the electrons injected from the n⁺ source region 6 through the channel-forming region 7 into the n⁻ drift layer 1 and arriving at the drain electrode 12. In order to ensure a rated voltage, a thickness of the n⁻ drift layer 1 must be increased corresponding to the increased depth of the second p⁺ region 21 than the p base region 17, which causes increase in the ON resistance. In order to keep the ON resistance at the original value, the planar size (area) of the chip must be increased, which causes an economic problem of an increased chip cost.

There is yet another method for avoiding turn ON of the parasitic bipolar transistor as shown in FIG. 13, in which the bottom part of the p base region 17 is formed in a configuration with a finite radius of curvature to eliminate a flat portion from the bottom part and the electric field is concentrated at the central part of the bottom part of the p base region 17, thereby concentrating the avalanche current at the central part. In order to obtain the bottom part in a configuration of a finite radius of curvature, a width of the opening for ion injection must be smaller than the depth of the p base region 17. The narrowed width of the opening causes difficulty in ensuring a sufficient contact area with the source electrode 13 at the opening part. Therefore, it is difficult in practice to make the opening necessarily and sufficiently narrow, and to concentrate the avalanche current at the bottom part in the structure.

### SUMMARY OF THE INVENTION

In view of the above-described problems, it is an object of the present invention to provide a MOS type semiconductor device and a manufacturing method thereof allowing production at a low cost without lowering a breakdown voltage and avoiding increase of an ON resistance.

In order to accomplish the object, a MOS type semiconductor device according to the present invention comprises: a semiconductor substrate having a drift layer of a first conductivity type in a front surfaced side of the substrate; a base region of a second conductivity type having a bottom part in a configuration with a finite radius of curvature and selectively disposed on a front surface region of the drift layer of the first conductivity type; a first region of the first conductivity type selectively disposed on a front surface region of the base region; a gate electrode disposed on a front surface of the base region between a surface of the first region and a surface of the drift layer interposing a gate insulation film between the front surface of the base region and the gate electrode; and a metal electrode in electrically conductive contact with the surface of the first region and the central part of the front surface of the base region; wherein a pn junction surface between the base region and the drift layer has centers of curvature both at the outside and inside of the base region.

Preferably, the net doping concentration in a part of the base region between adjacent well regions of the plurality of well regions is higher than the net doping concentration in a laterally peripheral end part of the base region.

Preferably, a MOS type semiconductor device of the invention further comprises a contact region of the second conductivity type selectively disposed on a front surface region of the base region, having a higher impurity concentration than that of the base region, and having a depth deeper than that of the first region, wherein an end of the contact region reaches a position right under the first region.

Preferably, the contact region of the second conductivity type has a configuration including a part or parts protruding outwardly and a part or parts protruding inwardly.

Preferably, a planar configuration of the base region is a polygon having corners with a finite radius of curvature, a circle, or a stripe.

Preferably, the MOS type semiconductor device is a MOS field effect transistor or an insulated gate bipolar transistor.

The object of the present invention is accomplished by a method of manufacturing a MOS type semiconductor device comprising steps of: forming an oxide film on a part of the surface of the drift layer of the first conductivity type, the part being to become the base region of the second conductivity type; and forming a first conductivity type region having a higher impurity concentration than that of the drift region of the first conductivity type using the oxide film as a mask, before a step of forming the baser region of the second conductivity type.

Preferably, in the method of the invention, the oxide film is a LOCOS oxide film.

Preferably, the method of the invention comprises a step of forming the base region having the plurality of well regions by a process of boron ion injection through an opening part prepared for forming the first region and a following process of thermal diffusion, before forming the first region.

Preferably, the method of the invention manufactures the MOS type semiconductor device as defined by claim 4 and comprises a step of forming the contact region of the second conductivity type by a process of boron ion injection through an opening part on a surface including a dent remained after removal of the LOCOS oxide film.

According to the invention, a MOS type semiconductor device and a manufacturing method thereof are provided that allow production at a low cost without lowering a breakdown voltage and avoiding increase of an ON resistance.

### BRIEF DESCRIPTION OF DRAWINGS

FIGS. 1(a), 1(b), and 1(c) are sectional views showing a wafer process for a MOSFET of Example 1 according to the present invention;

FIG. 2 is a sectional view of a part of a MOSFET of Example 1 according to the present invention;

FIG. 3 is a sectional view showing a wafer process for a MOSFET of Example 2 according to the present invention;

FIG. 4 is a sectional view of a part of a MOSFET of Example 2 according to the present invention;

FIG. 5 is a sectional view of a part of a MOSFET of Example 2 according to the present invention;

FIG. 6 is a sectional view of a part of an IGBT of Example 3 according to the present invention;

FIG. 7 is a planar view of a part of the MOSFET of FIG. 2 or FIG. 4 having a cell pattern of squares;

FIG. 8 is a planar view of a part of the MOSFET of FIG. 2 or FIG. 4 having a cell pattern of stripes;

FIG. 9 is a sectional view of an essential part of a conventional MOSFET;

FIG. 10 is a sectional view of an essential part of a conventional IGBT;

FIG. 11 is a sectional view of an essential part of a conventional MOSFET overlapped by an equivalent circuit of the MOSFET;

FIG. 12 is a sectional view of an essential part of a conventional MOSFET showing a path of avalanche current;

FIG. 13 is a sectional view of an essential part of a conventional MOSFET;

FIG. 14 is a sectional view of an essential part of a conventional MOSFET;

FIG. 15 is a sectional view of an essential part of a conventional IGBT;

FIG. 16 is a sectional view of a part of a MOSFET of Example 1 according to the present invention showing lines of equal net doping concentration; and

FIG. 17 is a sectional view of a part of a MOSFET of Example 4 according to the present invention.

### DETAILED DESCRIPTION OF THE INVENTION

Some preferred embodiments of a MOS type semiconductor device according to the present invention are described in detail in the following with reference to accompanying drawings. The present invention is not limited to the examples as long as it does not exceed the spirit and scope of the invention.

### Example 1

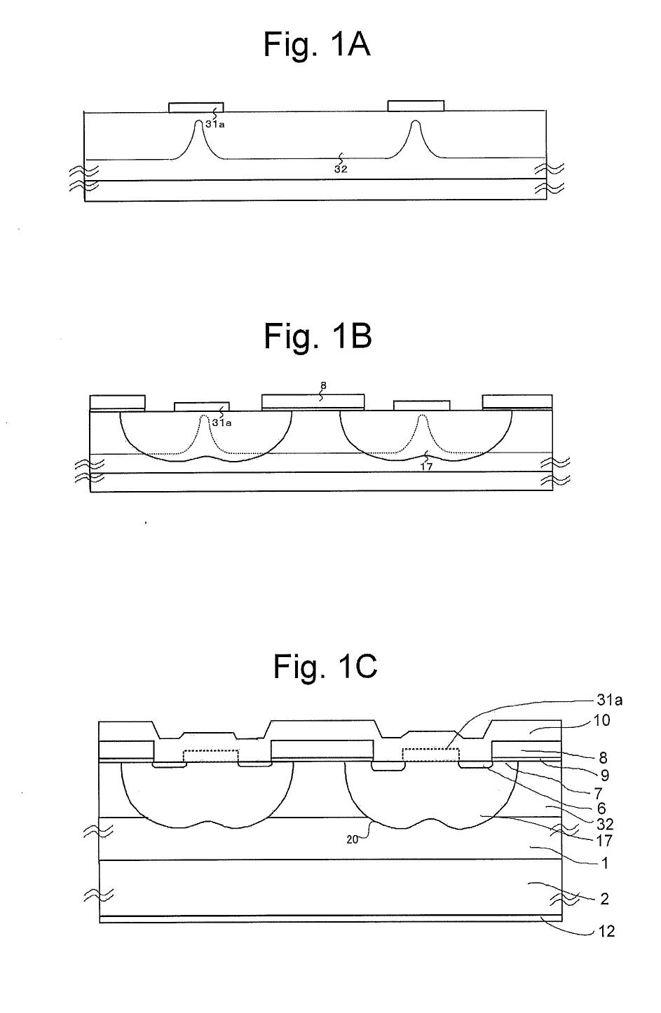

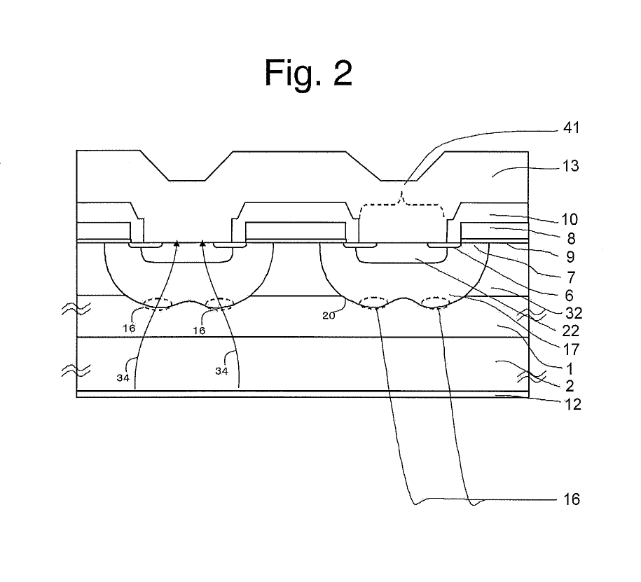

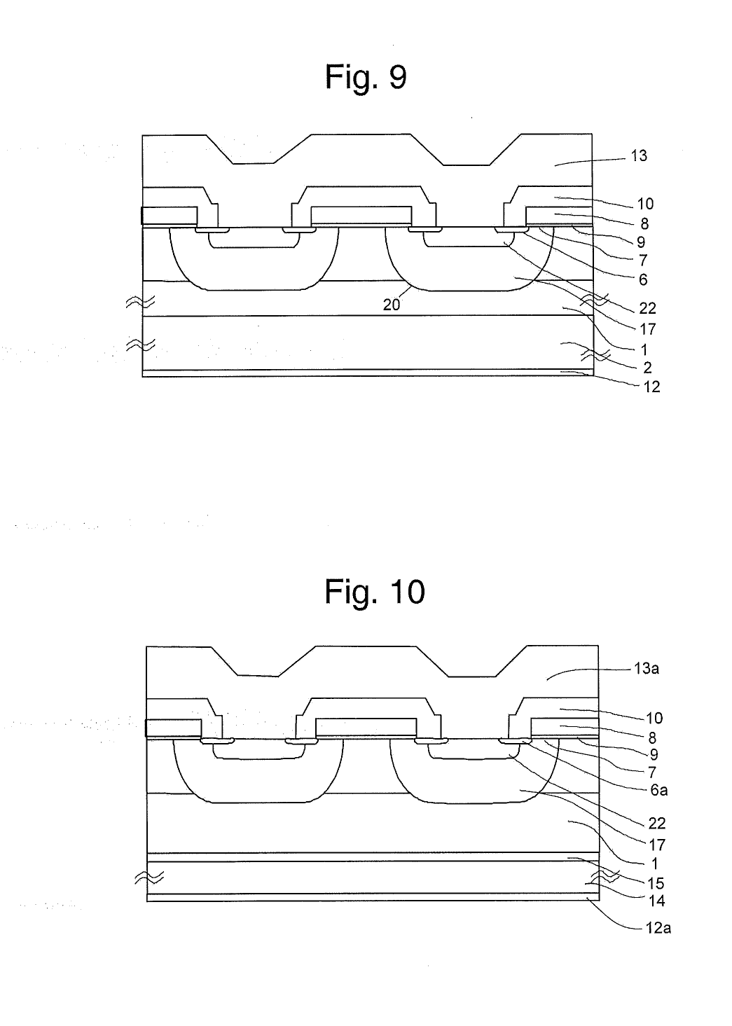

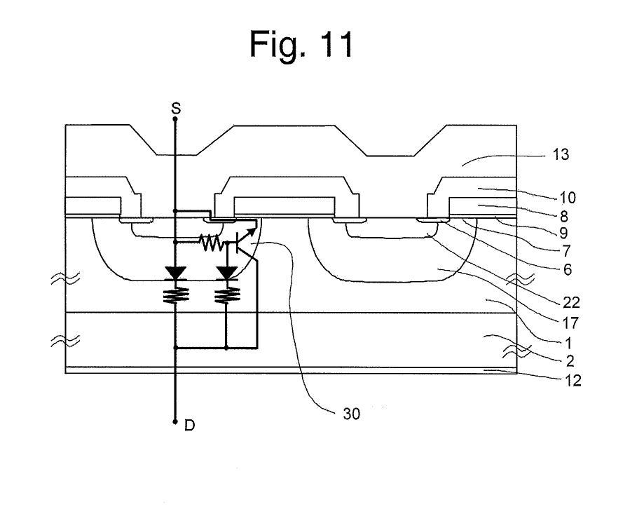

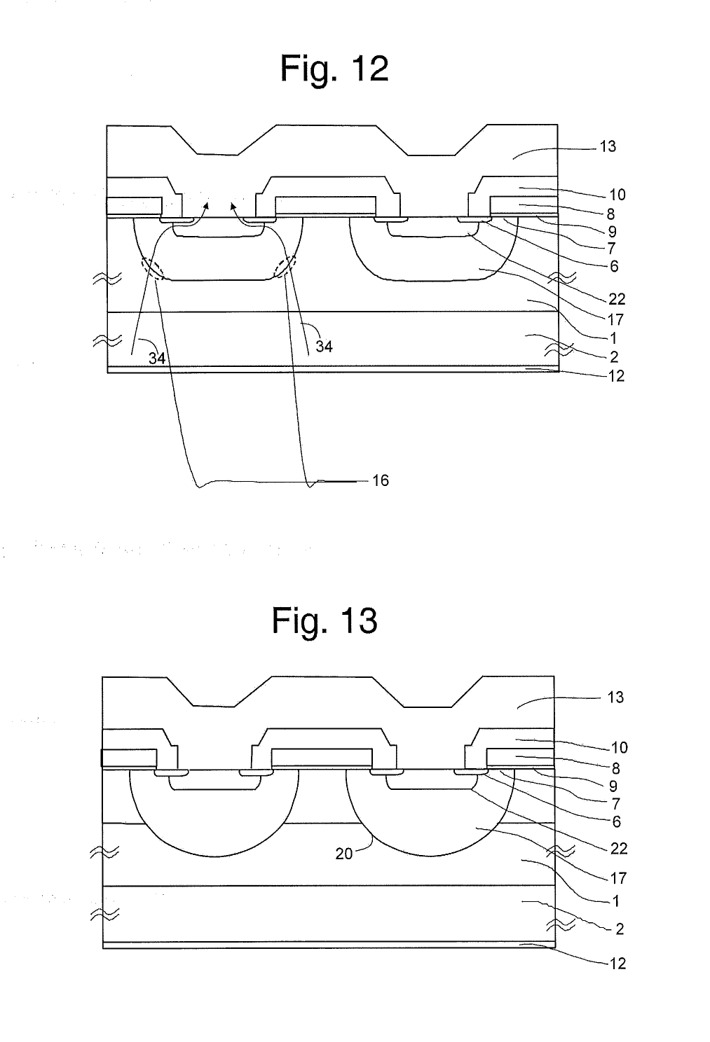

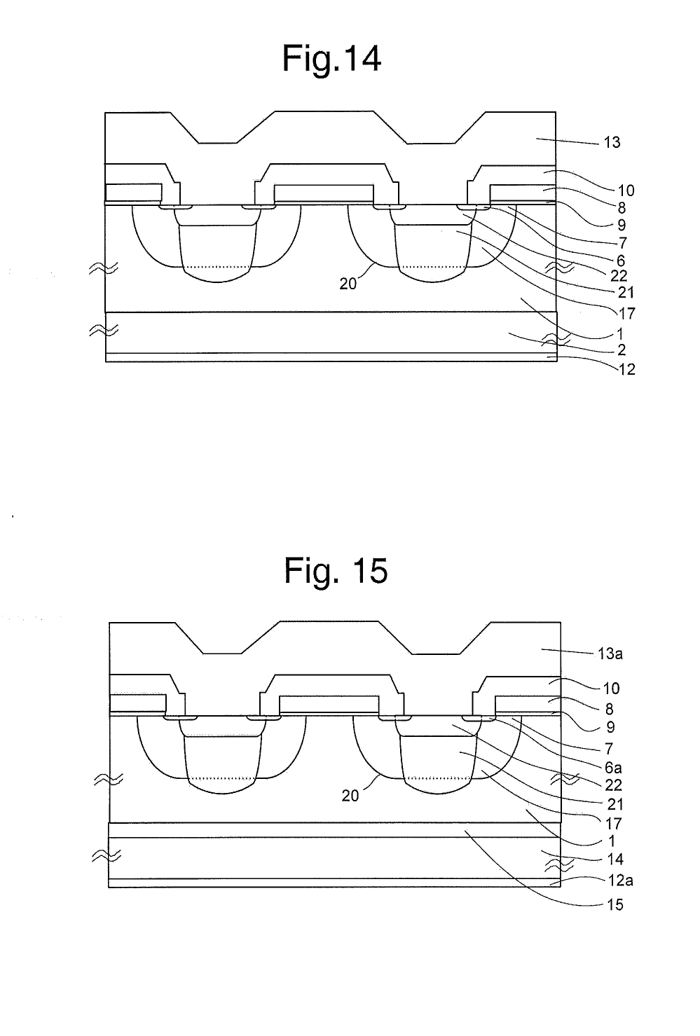

FIGS. 1(a), 1(b), and 1(c) are sectional views showing a wafer process for a MOSFET of Example 1 according to the present invention. FIG. 2 is a sectional view of a part of a MOSFET of Example 1 according to the present invention. The same symbols are given to the parts common with the parts in FIG. 9, which has been referred to in the description of the conventional MOSFET. FIGS. 1(a), 1(b), and 1(c) are sectional views of a part of a MOSFET in the wafer process up to a step of covering the whole front surface including a gate electrode 8 with an interlayer dielectric film 10.

The following description is made for the case of a MOSFET. A semiconductor substrate is used that is composed of a high concentration n⁺ silicon substrate to become an n⁺ drain layer 2 and an n⁻ drift layer 1 with high resistivity deposited on the n⁺ silicon substrate by epitaxial growth. An oxide film 31a is formed with a width equivalent to a distance between n⁺ source regions 6 formed on the front surface region of a p base region 17 in a later step. An n region 32 is formed by injecting a donor dopant such as phosphorus as shown in FIG. 1(a), the n region 32 being shallower than the p base region 17 and having an impurity concentration that is lower than that of the p base region 17 by one order of magnitude and higher than that of the n⁻ drift layer 1 by two orders of magnitude. The n regions 32 can be continued at the lateral diffusion edges thereof at right under the oxide film 31a as illustrated in FIG. 1(a), or can be separated from each other at that place. Then, a gate insulation film 9 and a polycrystalline silicon layer, which becomes a gate electrode 8, are laminated on the front surface of the silicon substrate. The polycrystalline silicon layer is patterned to form the gate electrode 8, leaving a gap between the gate electrode 8 and the oxide film 31a creating an opening part for forming the p base region 17. The p-base region 17 is formed by injecting acceptor dopant such as boron through the opening part as shown in FIG. 1(b). The width of the opening part is made smaller than a depth of the p base region 17 in order to form the p base region 17 having a non-flat bottom part.

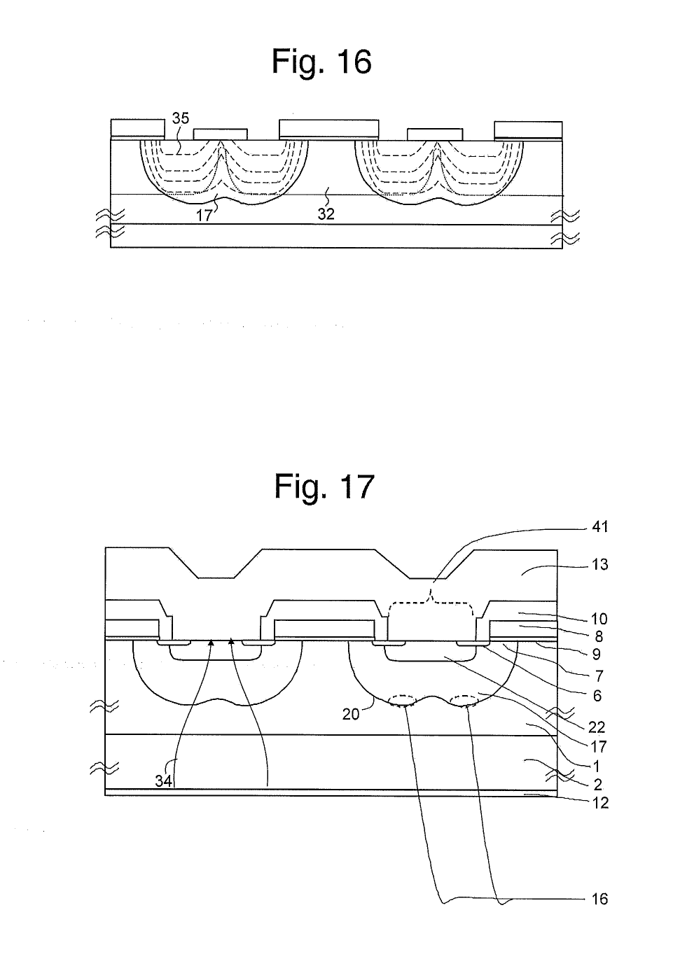

Since the width of the opening part is smaller than the depth of the p base region 17, the p base region 17 is obtained having a pn junction surface including a bottom part that has portions of peak curvature under the opening parts. Since the opening parts are formed at the both sides of the oxide film 31a on the p base region 17, the p base region 17 has two parts of peak curvature as shown in FIG. 1(b). For the pn junction surface including protruding and recessed portions, a center of curvature exists not only inside the p base region 17 but also outside the p base region 17. Thus, the center of curvature of the pn junction surface is located outside the p base region 17 at the center region of inwardly protruding portion of the pn junction surface as shown in FIG. 1(b). Thus, the p base region 17 is formed having two well regions that are the two parts of peak curvature. In regions of the p base region 17 overlapped by the n region 32, compensation of acceptor and donor densities occurs particularly at the lateral end regions of the p base region 17 under the gate electrode 8. As a result, lines of equal net doping concentration 35, as shown in FIG. 16, have a curvature smaller at the region between the two well regions in the p base region 17 right under the oxide film 31a without the donor diffusion than at the region occurring compensation of concentration due to overlapping of the p base region 17 and the n region 32. The line of equal net doping concentration is a line drawn along the points where a net concentration of the donor concentration subtracted by the acceptor concentration is a certain constant value. The net doping concentration is higher at the region between the two well regions in the p base region 17 than at the lateral end of the p base region 17 under the gate electrode 8.

Moreover, in both of a case where the n region 32 is formed uniformly and a case where the n region 32 is not formed, the net doping concentration at the region between the two well regions in the p base region 17 is higher than the net doping concentration at the lateral end of the p base region 17 under the gate electrode 8 as long as the two well regions have a overlapped region. By forming a region without the diffusion of the n region 32 using the mask of the oxide film 31a, the net doping concentration at the region between the two well regions in the p base region 17 is made as much higher than the net doping concentration at the lateral end region of the p base region 17 under the gate electrode 8.

The mask of the gate electrode 8 and the oxide film 31a is utilized again to form an n⁺ source region 6 by injection of donor ions such as arsenic. Subsequently, the whole front surface is covered by the interlayer dielectric film 10 as shown in FIG. 1(c). The interlayer dielectric film 10 is removed excepting the portion above the gate electrode 8 by photolithography employing an etching process as shown in the sectional view of FIG. 2. At the same time, the oxide film 31a is removed as well to form a contact window 41 for contact with the source electrode 13.

Boron ions are injected through this contact window 41 to form a p⁺ contact region 22. The p⁺ contact region 22 is formed on the surface region from which the oxide film 31a has been removed by an etching process as shown in FIG. 1(c). The n⁺ source region 6, however, remains because the impurity concentration of the n⁺ source region 6 is higher than that of the p⁺ contact region 22. Since the p⁺ contact region 22 is deeper than the n⁺ source region 6, the p⁺ contact region 22 is formed also beneath the n⁺ source region 6. The source electrode 13 is deposited commonly in contact with the surface of the n⁺ source region 6 and the surface of the p⁺ contact region 22 and covering the gate electrode 8 through the interlayer dielectric film 10. The gate electrode 8 is made in contact with and wired to an aluminum gate pad electrode disposed at an undepicted separate place on the chip surface. A drain electrode 12 is formed on the surface of the n⁺ drain layer 2, which is a reversed surface side of the source electrode side. Thus, the wafer process is completed for a MOSFET of Example 1 according to the present invention.

FIG. 7 is a plan view of the MOSFET of FIG. 2 having a front surface MOS structure of a cell pattern of squares. A MOSFET having the front surface MOS structure as shown in FIG. 7 with a square cell pattern is obtained in a wafer process using a mask for forming the p base region 17 that is formed in the square cells by opening contact windows 41 in the polycrystalline silicon layer that forms the gate electrode 8. The square in the cell pattern can be changed to another shape such as a rectangle, a hexagon, a triangle, or a circle. Corners of the square, rectangle, hexagon, or triangle are preferably chamfered roundly as shown in FIG. 7 for the case of a square. Such a configuration mitigates concentration of electric field at the corners on the time of voltage application.

FIG. 8 is a plan view of a MOSFET of FIG. 2 having a front surface MOS structure with a cell pattern of stripes. Such a MOSFET is obtained in a wafer process using a mask for forming the p base region 17 that is formed in a configuration of stripes by opening contact windows 41 in the polycrystalline silicon layer that forms the gate electrode 8. The cell pattern of MOS structure in the configuration of stripes includes the p⁺ contact region 22, the n⁺ source region 6, the channel forming region 7, and the n⁻ drift layer 1 arranged in parallel as shown in FIG. 8. The p base region 17 having a bottom part including two portions protruding outwardly (or downwardly) as described previously, can have longitudinal ends of the stripes either continuous like a racetrack or opened as simple stripes. Thus, the p base region 17 can be formed as a single layer continuous at the longitudinal ends, or a plurality of stripes or cells arranged separately from each other. The p base region 17 either in a single layer or separately arranged, is basically at the same electric potential as the source electrode 13 in an OFF state.

A MOSFET of the invention having the above-described construction concentrates avalanche current 34 on an event of breakdown at avalanche arising parts 16 indicated by dotted circles in the deepest places of the p base region 17 as shown in FIG. 2. A p⁺ contact region 22 is disposed above the avalanche arising parts 16, and a net doping concentration in the part of overlapped two well regions of the p base region 17 is higher than the net doping concentration of the lateral ends of the p base region 17 under the gate electrode 8. These situations prevent the acceptor concentration from decreasing in the central region, making the region in low resistivity. Therefore, the avalanche current 34 tends to run in the central region more readily. As a result, an electric current that would flow into the part of the p base region 17 right under the n⁺ source region 6 is suppressed inhibiting turn ON of a parasitic bipolar transistor. Thus, breakdown of the device is avoided in the turn OFF process with an inductive load.

The p base region 17 in Example 1, having two well regions in the above description, can be provided with well regions more than two, for example three well regions. Then, the avalanche occurs at the bottom parts of the three well regions. The avalanche current generated at the bottom of the middle well region of the three well regions flows directly into the p⁺ contact region right above the middle well region according to electrostatic potential distribution. As a result, avalanche current flowing right under the n⁺ source region 6 almost vanishes. The three or more well regions can be formed by providing two or more oxide films 31a like shown in FIGS. 1(a) through 1(c).

### Example 2

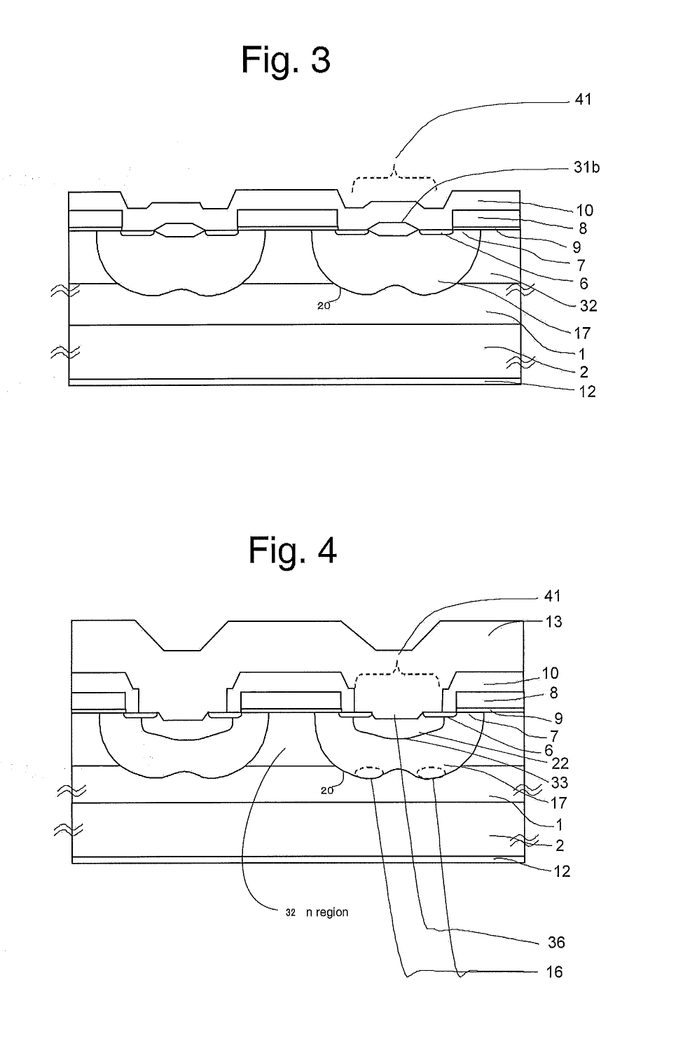

FIGS. 3 and 4 are plan views of a part of a MOSFET of Example 2 according to the present invention. The same symbols are given to the parts similar to those in FIG. 9. FIG. 3 is a sectional view of a part of a MOSFET in the state at the process step in which the whole front surface including the area on the gate electrode 8 has been covered with an interlayer dielectric film 10.

First, a semiconductor substrate is prepared consisting of an n⁺ drain layer 2 and an n⁻ drain layer 1 with a high resistivity formed by epitaxial growth on the n⁺ drain layer 2. A LOCONS oxide film 31b, different from the oxide film 31a in Example 1, is formed by means of a LOCOS process so that the silicon surface has a recessed portion. Using this oxide film 31b as a mask, a dopant such as phosphorus is injected to form an n region 32 that has a depth shallower than the p base region 17 and with an impurity concentration lower than that in the p base region 17 by one order of magnitude and higher than that in the n⁻ drift layer 1 by two order of magnitude. Then, a gate insulation film 9 and a polycrystalline silicon layer to become a gate electrode 8 are sequentially formed on the n⁻ drift layer 1. The gate electrode 8 is formed by opening a contact window 41 in a portion of the polycrystalline silicon layer including the LOCOS oxide film 31b by means of a photolithography process. The LOCOS oxide film 31b is made remained in the middle area of the window 41. The gap between the LOCOS oxide film 31b and the gate electrode 8 is made smaller than the depth of the p base region 17 that is formed in the next step.

Using the gate electrode 8 and the LOCOS oxide film 31b as masks, processes of boron ion injection and following thermal diffusion are conducted to form a p base region 17 under the opening area. The resulted p base region 17 includes two well regions with a bottom portion having two outwardly (downwardly) protruding parts under the opening area, obtaining a pn junction surface 20 having the two well regions as shown in FIG. 3. Then, using the gate electrode 8 and the LOCOS oxide film 31b as masks again, donor ions such as arsenic are injected to form an n⁺ source region 6. Subsequently, an interlayer dielectric film 10 is deposited covering the whole front surface. FIG. 3 shows a state at the end of this step. After that, as shown in the sectional view of the part of FIG. 4, the interlayer dielectric film 10 except for the area on the gate electrode 8 is removed by an etching process in a photolithography method. The LOCOS oxide film 31b is simultaneously removed, to form a contact window 41 for a source electrode 13 to be made in contact with the front surface in the area of the contact window 41. The front surface in the area of the windows 41 includes an oxide film imprint 36 that is a dent part formed after removal of the LOCOS oxide film 31b. Boron ions are injected through the contact window 41 to form a p⁺ contact region 22. Owing to the dent part on the surface, the p⁺ contact region 22 has a bottom face that has the deepest part at the central part 33 protruding outwardly (downwardly) and the curved parts protruding inwardly at both sides of the central part 33. A source electrode 13 is deposited commonly in contact with the surface of the n⁺ source region 6 and the surface of the p⁺ contact region 22 and covering the gate electrode 8 through the interlayer dielectric film 10. The gate electrode 8 is made in contact with and wired to an aluminum gate pad electrode disposed at an undepicted separate place on the chip surface. A drain electrode 12 is formed on the rear side surface of the n⁺ drain layer 2, which is a reversed surface side of the source electrode side. Thus, the wafer process is completed for a MOSFETT of Example 2 according to the present invention.

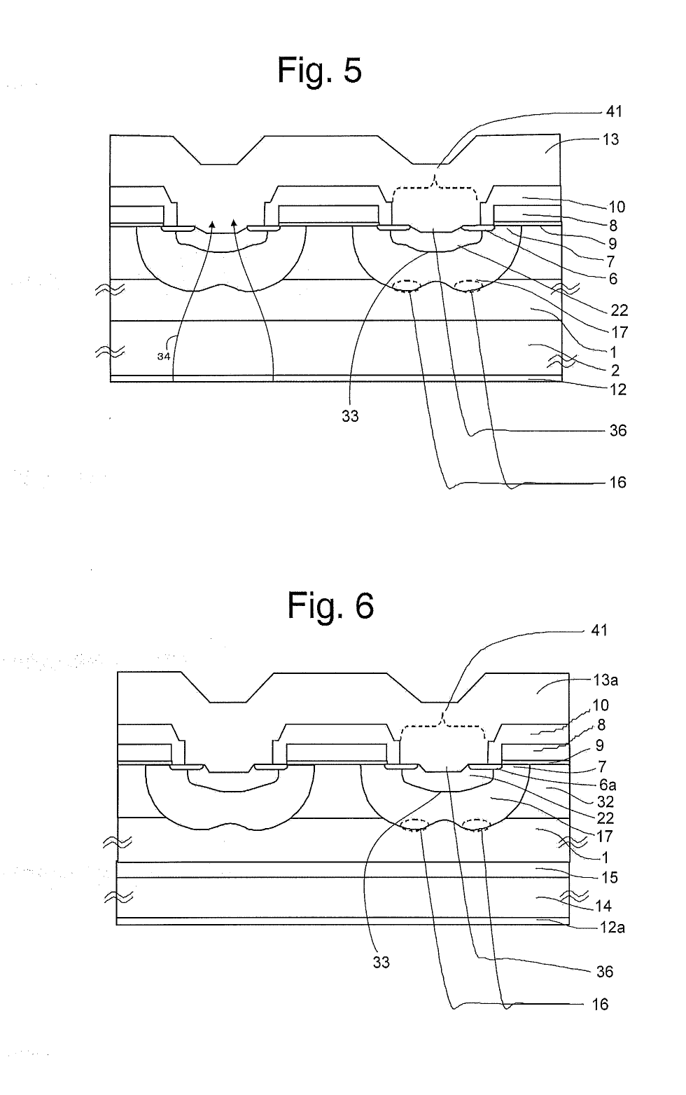

The p base region 17 has a pn junction surface 20 in a configuration having two well regions at the interface with the n⁻ drift layer 1. The bottom part of the two well regions is the deepest at the middle between the oxide film imprint 36 formed by removal of the LOCOS oxide film 31b and the edge of the gate electrode 8. The two bottom parts of the well region become avalanche arising parts 16. The p⁺ contact region 22, owing to a dent part on the silicon surface formed by the effect of the oxide film imprint 36 as shown in FIG. 4, can be formed in a configuration that has the deepest part protruding outwardly (downwardly) around the central part 33 of the bottom part of the p⁺ contact region 22 combined with the parts protruding inwardly at both sides of the central part 33. Owing to these inwardly protruding parts, the bottom part of the p⁺ contact region 22 can be formed downwardly protruding at the central part 33. As a result, the avalanche current 34 is readily concentrated in the p⁺ contact region 22 as shown in FIG. 5. This shape of the p⁺ contact region 22 in combination of the outwardly protruding part and the inwardly protruding parts allows the central part 33 separated from the n⁺ source region 6, thereby effectively suppressing reach-through of a depletion layer to the n⁺ source layer 6.

The p base region 17 in the MOSFET of Example 2 as described above has, like in Example 1, the avalanche arising parts 16 in which electric field concentration tends to occur. In addition, the bottom part of the p⁺ contact region 22 is not flat but has a deep part at the central part 33. As a result, the electric current flowing-in through the avalanche arising parts 16 tends to go towards the central part 33 of the p⁺ contact region 22 as indicated by the arrows in FIG. 5. Therefore, the parasitic bipolar transistor action is more suppressed than in Example 1.

### Example 3

In the rear surface side that is the opposite side of the front surface side described above, a p⁺ collector layer can be formed on the reversed side surface of the n⁻ drift layer interposing an n⁺ buffer layer, producing a structure of an IGBT. In the case of an IGBT, a parasitic thyristor is contained in place of the parasitic bipolar transistor contained in the MOSFET. The parasitic thyristor, like the parasitic bipolar transistor in the MOSFET, can be inhibited to turn ON, thereby avoiding breakdown of the device as described in the following.

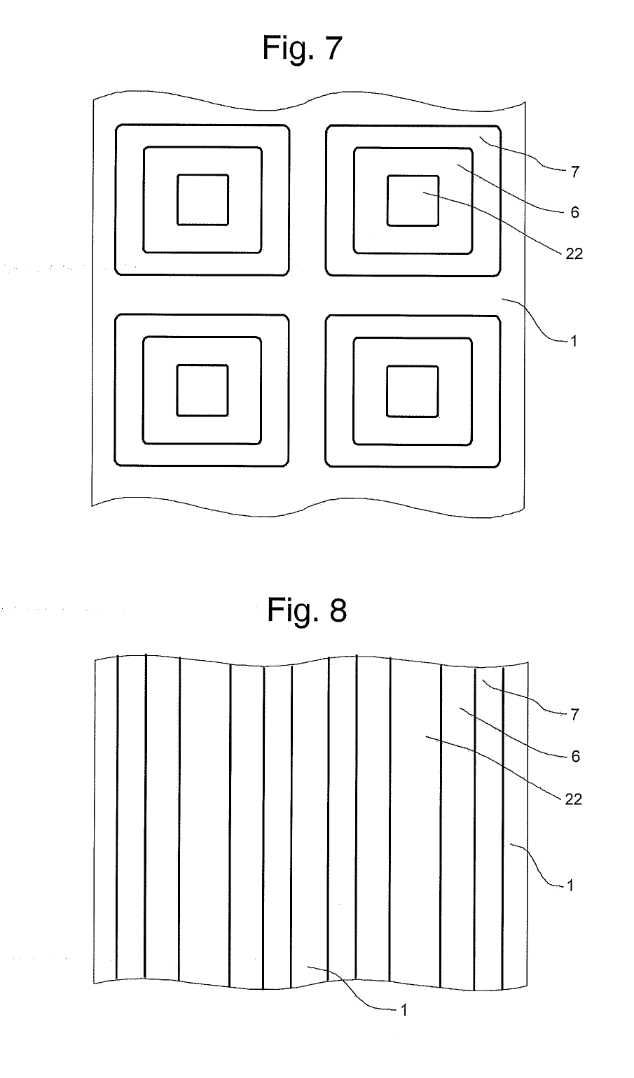

An IGBT of Example 3 is described here in detail. FIG. 6 is a sectional view of a part of the IGBT of Example 3 according to the present invention. The same symbols are given to the parts similar to those in FIG. 9. The IGBT of FIG. 6 is different from the MOSFET of FIG. 4 in that the IGBT comprises a p⁺ collector layer 14, an n⁺ buffer layer 15 interposed between the p⁺ collector layer 14 and then drift layer 1, and a collector electrode 12a formed on the rear side surface of the p⁺ collector layer 14. Names of the parts are changed from the n⁺ source region 6 to an n⁺ emitter region 6a, and from the source electrode 13 to an emitter electrode 13a. Like in the structure of FIG. 4, the p base region 17 has a pn junction surface 20 in a configuration including a part(s) with a finite radius of curvature at the interface with the n⁻ drift layer 1. The depth from the front surface to the pn junction surface 20 is deepest at a middle position between the oxide film imprint 36 formed after removing the LOCOS oxide film and the edge of the gate electrode 8, and shallowest at the position under the central part 33 of the p⁺ contact region 22.

The p⁺ region 22 is deepest at the central part 33. The thickness of the n⁻ drift layer 1 is the thinnest at the places of the deepest pn junction surface 20, and an avalanche phenomenon starts at these places on reversed biasing.

### Example 4

Example 4 according to the present invention is described with reference to FIG. 17. Example 4 has a structure similar to the structure of Example 1 as shown in FIG. 2 from which the n region 32 is eliminated. Without the n region 32, a p base region 17 can still be formed to have two well regions protruding outwardly (downwardly). The p base region 17 having two outwardly protruding well regions can be formed, despite without the n region 32, by a process of boron ion injection through the opening between the oxide film 31a and the gate electrode 8 as depicted in FIG. 1(b) and a process of followed thermal diffusion. Consequently, the position of avalanche current can be shifted to the avalanche arising parts 16 at the bottom of the two well regions, and the avalanche current 34 can be lead to the source electrode 13 preventing the current from flowing through the place right under the n⁺ source region 6. Therefore, the problems of decreased breakdown voltage and increased ON resistance described previously can be solved by a structure without the n region as well. However, it is, of course, preferable to provide an n region, as described previously.

As described thus far, every MOS semiconductor device described in Example 1 through Example 4 according to the present invention comprises a p base region 17 that includes a p⁺ contact region 22 and has parts with a finite radius of curvature. The p base region 17 comprises two avalanche arising parts 16 protruding outwardly (downwardly) at the places that are deepest from the front surface of the p base region 17 and located under the n⁺ source regions 6 or the n⁺ emitter regions 6a. This construction inhibits turning ON of a parasitic bipolar transistor or a parasitic thyristor that is formed of the p base region 17 and the n⁺ drain layer 2 or the n⁺ emitter region 6a. This construction inhibits turning ON of a parasitic bipolar transistor or a parasitic thyristor that is formed of the p base region 17 and n⁺ drain layer 2 or formed of the p base region 17 and the p⁺ collector layer 14 of the MOS type semiconductor device. Therefore, avalanche withstand capability is improved without lowering a breakdown voltage or increasing an ON resistance of a device. Moreover, the construction of the invention reduces manufacturing costs by solving the problem of decrease in yielded number of chips due to increased chip size and the problem of increase in fabrication steps.

What is claimed is:

1. A MOS (metal oxide semiconductor) type semiconductor device comprising:
a semiconductor substrate having a drift layer of a first conductivity type disposed at a front portion of the substrate;
a base region of a second conductivity type having a bottom part in a configuration with at least one finite radius of curvature and selectively disposed at a front surface region of the drift layer of the first conductivity type, wherein
a pn junction surface between the base region and the drift layer has centers of curvature both at the outside and inside of the base region;
a first region of the first conductivity type selectively disposed at a front surface region of the base region:
a gate insulation film disposed on a front surface of the base region;
a gate electrode disposed on a front surface of the gate insulation film, wherein the gate insulation film is interposed between the front surface of the base region, the gate electrode, and a surface of the first region; and
a metal electrode in electrically conductive contact with a surface of the first region and the central part of the front surface of the base region.

2. The MOS type semiconductor device according to claim 1, wherein the net doping concentration in a part of the base region between a plurality of adjacent well regions is higher than the net doping concentration in a laterally peripheral end part of the base region.

3. The MOS type semiconductor device according to claim 1, further comprising a contact region of the second conductivity type selectively disposed at a front surface region of the base region, having a higher impurity concentration than that of the base region, and having a depth deeper than that of the first region, wherein an end of the contact region reaches a position directly under the first region.

4. The MOS type semiconductor device according to claim 3, wherein the contact region of the second conductivity type has a configuration including at least one part protruding outwardly and at least one part protruding inwardly.

5. The MOS type semiconductor device according to claim 1, wherein a planar configuration of the base region is a polygon having corners with a finite radius of curvature, a circle, or a stripe.

6. The MOS type semiconductor device according to claim 1, wherein the MOS type semiconductor device is a MOS field effect transistor.

7. The MOS type semiconductor device according to claim 1, wherein the MOS type semiconductor device is an insulated gate bipolar transistor.

8. A method of manufacturing the MOS (metal oxide semiconductor) type semiconductor device as defined by claim 1, the method comprising:
forming an oxide film on a part of the surface of the drift layer of the first conductivity type, the part being a portion of the base region of the second conductivity type; and
forming a first conductivity type region having a higher impurity concentration than that of the drift region of the first conductivity type using the oxide film as a mask, before a step of forming the base region of the second conductivity type.

9. The method of manufacturing the MOS type semiconductor device according to claim 8, wherein the oxide film is a LOCOS oxide film.

10. The method of manufacturing the MOS type semiconductor device according to claim 8, further comprising forming the base region having a plurality of well regions by a process of boron ion injection through an opening part prepared for forming the first region and a subsequent process of thermal diffusion, prior to forming the first region.

11. The method of manufacturing a MOS type semiconductor device according to claim 9, further comprising forming the contact region of the second conductivity type by a process of boron ion injection through an opening part on a surface including a dent remaining after removal of the LOCOS oxide film.
